(19) United States
(12) Patent Application Publication
(10) Pub. No.: US 2026/0250876 A1
(43) Pub. Date: Aug. 27, 2026

(54) SUBSTRATE PROCESSING APPARATUS

(71) Applicant: EBARA CORPORATION, Tokyo (JP)

(72) Inventors: Masaya SEKI, Tokyo (JP); Masaki TOMITA, Tokyo (JP); Nobuya YAMADA, Tokyo (JP)

(21) Appl. No.: 18/726,346

(22) PCT Filed: Aug. 23, 2023
(86) PCT No.: PCT/JP2023/030227

§ 371 Date: Jul. 2, 2024

(51) Int. Cl. C25D 21/04; C25D 17/00; C25D 21/06

(52) U.S. Cl. CPC C25D 21/04; C25D 17/001; C25D 21/06

(57) ABSTRACT

A substrate processing apparatus that can efficiently clean the inside of the apparatus is achieved. A plating apparatus includes a substrate transfer chamber (701), a fan filter unit (408), a plating chamber (401), an exhaust chamber (702), a partition member (720), and a bypass flow channel (730). The substrate transfer chamber (701) houses a transfer device for transferring a substrate. The fan filter unit (408) is disposed above the substrate transfer chamber (701) and configured to supply a gas to the substrate transfer chamber (701). The plating chamber (401) is disposed on a side of the substrate transfer chamber (701) and houses a plating module (400) for performing a plating process on the substrate. The exhaust chamber (702) is disposed below the substrate transfer chamber (701). The partition member (720) is disposed between the substrate transfer chamber (701) and the exhaust chamber (702). The substrate transfer chamber (701) and the exhaust chamber (702) communicate through the bypass flow channel (730) by bypassing the partition member (720). The plating chamber (401) has a supply port (404) for supplying the gas supplied to the substrate transfer chamber (701) by the fan filter unit (408) to the plating chamber (401), and a discharge port (405) for discharging the gas supplied to the plating chamber (401) to outside. The exhaust chamber (702) has an exhaust outlet (703) for discharging the gas supplied to the exhaust chamber (702) via the bypass flow channel (730) to outside.

### TECHNICAL FIELD

This application relates to a substrate processing apparatus.

### BACKGROUND ART

A substrate processing apparatus for performing various processes on a surface to be processed of a substrate (for example, a semiconductor wafer) is known. The substrate processing apparatus is, for example, an electroplating apparatus for forming a conductive film on a surface to be plated of a substrate, or a chemical mechanical polishing (CMP) device for polishing and planarizing a surface to be polished of a substrate.

The substrate processing apparatus disclosed in PTL 1 includes a transfer device for transferring substrates, a substrate processing rack disposed on the side of the transfer device, and a fan disposed above the transfer device and the substrate processing rack. The substrate processing apparatus is configured to form a downflow inside the apparatus by sending air vertically downward from the fan to clean the inside of the apparatus.

### CITATION LIST

### Patent Literature

PTL 1: U.S. Pat. No. 8,066,466 B2

### SUMMARY OF INVENTION

### Technical Problem

However, since the substrate processing apparatus disclosed in PTL 1 is configured to form the downflow throughout the inside of the apparatus, a large amount of air is required to be sent from the fan in order to properly clean the inside of the apparatus. Therefore, the number of fans increases, the size of the fan increases, and as a result, the whole apparatus becomes larger in size, which is undesirable.

Therefore, it is one object of this application to achieve a substrate processing apparatus that can efficiently clean the inside of the apparatus.

### Solution to Problem

According to one embodiment, a substrate processing apparatus is disclosed. The substrate processing apparatus includes a substrate transfer chamber, a fan module, a plating chamber, an exhaust chamber, a partition member, and a bypass flow channel. The substrate transfer chamber houses a transfer device for transferring a substrate. The fan module is disposed above the substrate transfer chamber and configured to supply a gas to the substrate transfer chamber. The plating chamber is disposed on a side of the substrate transfer chamber and houses a plating module for performing a plating process on the substrate. The exhaust chamber is disposed below the substrate transfer chamber. The partition member is disposed between the substrate transfer chamber and the exhaust chamber. The substrate transfer chamber and the exhaust chamber communicate through the bypass flow channel by bypassing the partition member. The plating chamber has a supply port for supplying the gas supplied to the substrate transfer chamber by the fan module to the plating chamber, and a discharge port for discharging the gas supplied to the plating chamber to outside. The exhaust chamber has an exhaust outlet for discharging the gas supplied to the exhaust chamber via the bypass flow channel to outside.

### BRIEF DESCRIPTION OF DRAWINGS

FIG. 1 is a perspective view illustrating an overall configuration of a plating apparatus according to one embodiment.

FIG. 2A is a plan view illustrating the overall configuration of the plating apparatus according to the one embodiment.

FIG. 2B is a cross-sectional view along the B-B line of FIG. 2A.

FIG. 2C is a cross-sectional view along the C-C line of FIG. 2B.

FIG. 3 is a cross-sectional view of a plating apparatus of a modification.

FIG. 4 is a cross-sectional view of a plating apparatus of a modification.

FIG. 5 is a cross-sectional view of a plating apparatus of a modification.

### DESCRIPTION OF EMBODIMENTS

The following describes embodiments of the present invention with reference to the drawings. In the drawings described later, identical reference numerals are assigned to identical or equivalent constituent elements, and therefore, such elements will not be described again. In the following embodiments, a plating apparatus exemplifies a substrate processing apparatus, but the present invention is not limited thereto, and this embodiment can be applied to a chemical mechanical polishing (CMP) apparatus for polishing and planarizing a surface to be polished of a substrate.

### Overall Configuration of Plating Apparatus

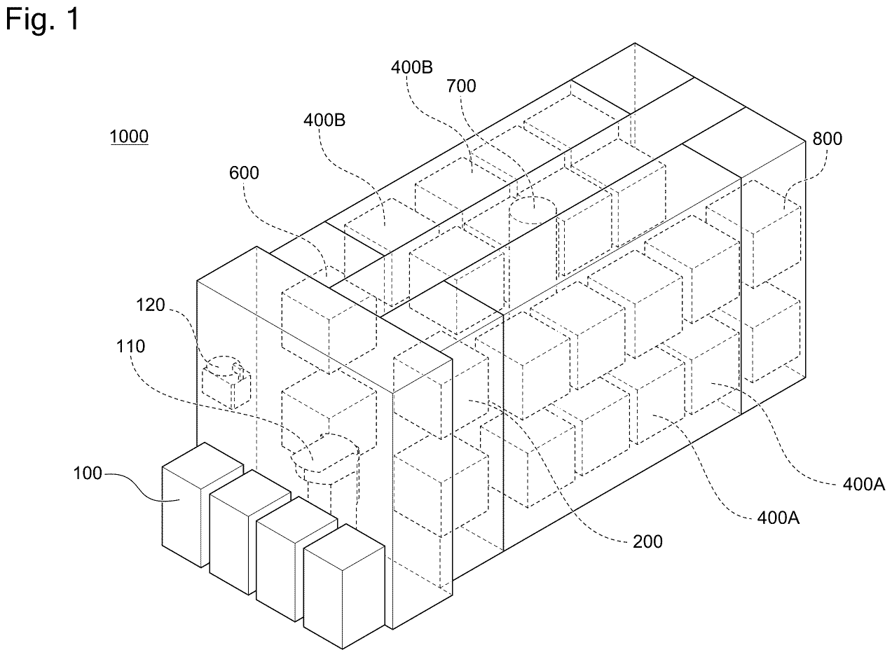

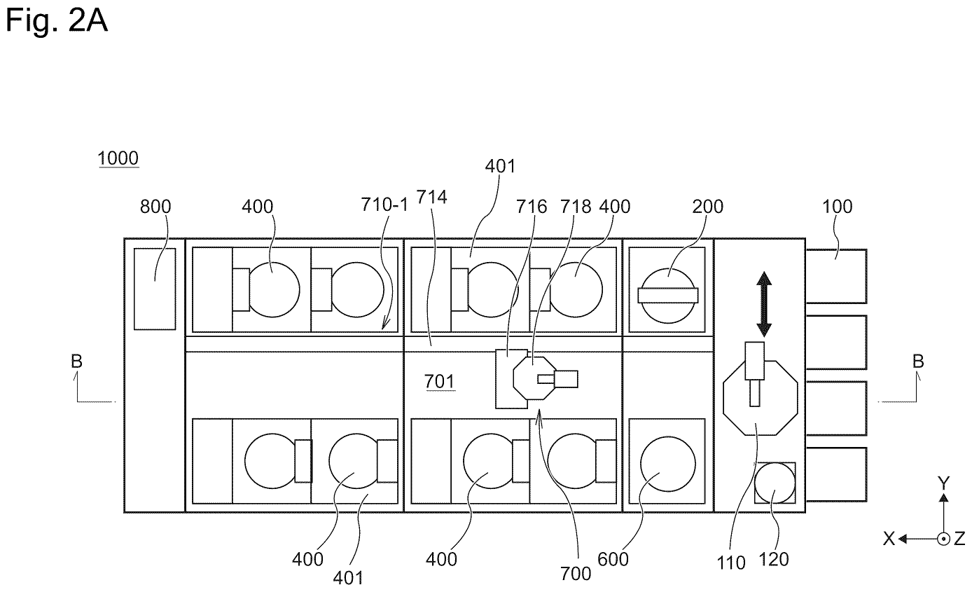

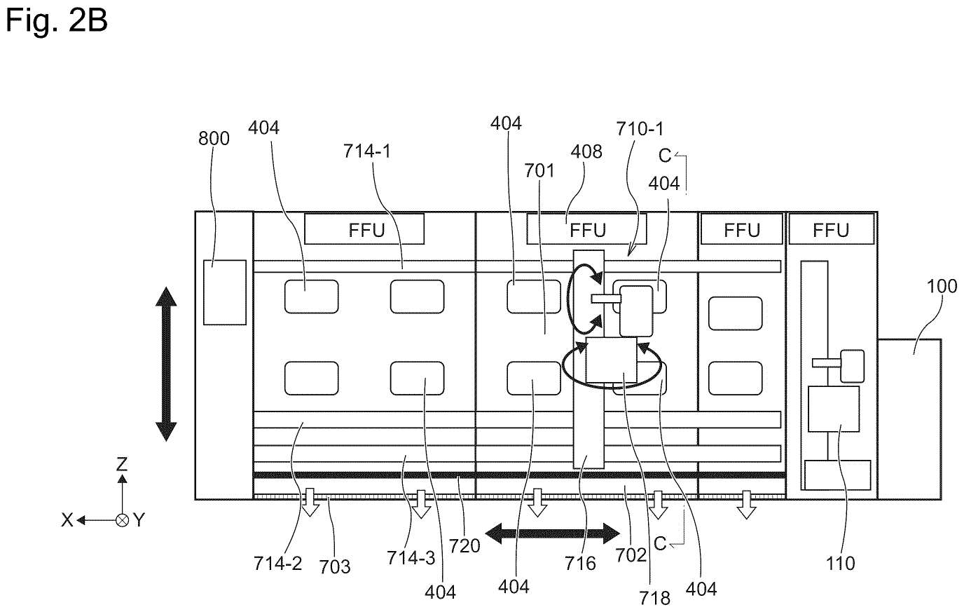

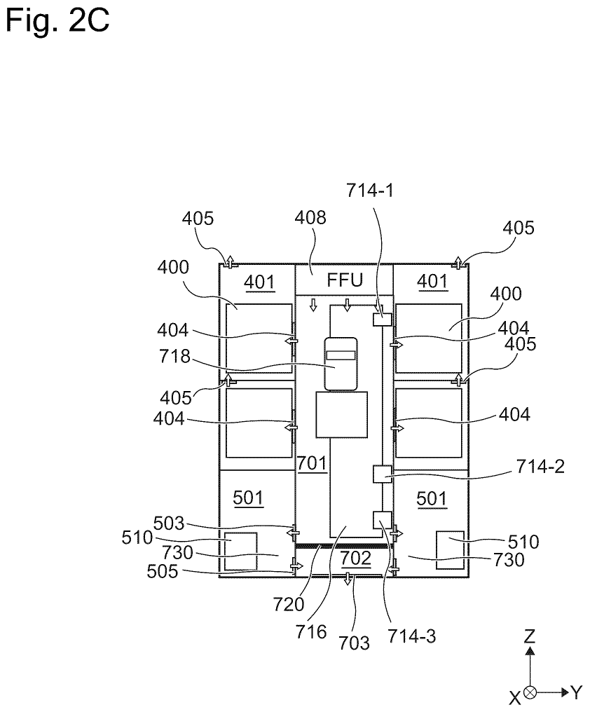

FIG. 1 is a perspective view illustrating an overall configuration of the plating apparatus of this embodiment. FIG. 2A is a plan view illustrating the overall configuration of the plating apparatus of this embodiment. As illustrated in FIGS. 1 and 2A, a plating apparatus 1000 includes load ports 100, a transfer robot 110, an aligner 120, pre-wet modules 200, plating modules 400, spin rinse dryers 600, a transfer device 700, and a control module 800.

The load port 100 is a module for loading a substrate housed in a cassette, such as a FOUP, (not illustrated) to the plating apparatus 1000 and unloading the substrate from the plating apparatus 1000 to the cassette. While the four load ports 100 are disposed to be arranged in the horizontal direction in this embodiment, the number and arrangement of the load ports 100 are arbitrary. The transfer robot (a dry robot) 110 is a robot for transferring the substrate and is configured to transfer the substrate between the load port 100, the aligner 120, the pre-wet module 200, and the spin rinse dryer 600.

The aligner 120 is a module for adjusting a position of an orientation flat, a notch, and the like of the substrate in a predetermined direction. While the one aligner 120 is disposed in this embodiment, the number and arrangement of the aligners 120 are arbitrary. The pre-wet module 200 wets a surface to be plated of the substrate before a plating process with a process liquid, such as pure water or deaerated water, to replace air inside a pattern formed on the surface of the substrate with the process liquid. The pre-wet module 200 is configured to perform a pre-wet process to facilitate supplying a plating solution to the inside of the pattern by replacing the process liquid inside the pattern with the plating solution during plating. While the two pre-wet modules 200 are disposed to be arranged in the vertical direction in this embodiment, the number and arrangement of the pre-wet modules 200 are arbitrary.

The plating module 400 is a module for performing the plating process on the substrate. In this embodiment, the plating modules 400 include eight plating modules 400A disposed on one side of a travel path of the transfer device 700 and eight plating modules 400B disposed on the opposite side of the travel path of the transfer device 700. In this embodiment, a total of the 16 plating modules 400 are provided, but the number and arrangements of the plating modules 400 are arbitrary.

The spin rinse dryer 600 is one configuration of a drying module for rotating and drying the substrate at high speed after the plating process. While the two spin rinse dryers are disposed to be arranged in the vertical direction in this embodiment, the number and arrangement of the spin rinse dryers are arbitrary. The transfer device 700 is a device for transferring the substrate between the plurality of modules inside the plating apparatus 1000. The control module 800 is configured to control the plurality of modules in the plating apparatus 1000 and can be configured of, for example, a general computer including input/output interfaces with an operator or a dedicated computer.

An example of a sequence of the plating processes by the plating apparatus 1000 will be described. First, the substrate housed in the cassette is loaded on the load port 100. Subsequently, the transfer robot 110 grips the substrate from the cassette at the load port 100 and transfers the substrate to the aligner 120. The aligner 120 adjusts the position of the orientation flat, the notch, or the like of the substrate in the predetermined direction. The transfer robot 110 transfers the substrate whose direction is adjusted with the aligner 120 to the pre-wet module 200.

The pre-wet module 200 performs the pre-wet process on the substrate. The transfer device 700 transfers the substrate on which the pre-wet process has been performed to the plating module 400. The plating module 400 performs the plating process on the substrate.

The transfer device 700 transfers the substrate on which the plating process has been performed to another plating module 400 for a composite plating process or transfers the substrate to the spin rinse dryer 600. The spin rinse dryer 600 performs a drying process on the substrate. The transfer robot 110 receives the substrate from the spin rinse dryer 600 and transfers the substrate on which the drying process has been performed to the cassette at the load port 100. Finally, the cassette housing the substrate is unloaded from the load port 100.

Next, details of the plating apparatus 1000 will be described. FIG. 2B is a cross-sectional view along the B-B line of FIG. 2A. FIG. 2C is a cross-sectional view along the C-C line of FIG. 2B. In FIG. 2A to FIG. 2C, for convenience, the transfer device 700 has a travel direction in an X direction, the transfer robot 110 has a travel direction in a Y direction, and the vertical direction is a Z direction.

The plating apparatus 1000 includes a substrate transfer chamber 701 extending in the X direction. The transfer device 700 is housed in the substrate transfer chamber 701. The plating apparatus 1000 includes a plurality of (in this embodiment, 16) plating chambers 401 disposed on both sides of the substrate transfer chamber 701 in the X direction. Each plating module 400 is disposed in the plating chamber 401. Although this embodiment illustrates an example in which the plating chambers 401 are arranged on both sides of the substrate transfer chamber 701 in the X direction, the plating chambers 401 are not limited thereto, and the plating chambers 401 may be arranged on only one side of the substrate transfer chamber 701 in the X direction.

### Configuration of Transfer Device

Next, details of the transfer device 700 will be described. As illustrated in FIG. 2, the transfer device 700 includes a mounting member 710-1 fixed to a side surface of the plating chamber 401, an elevating rail 716 attached to the mounting member 710-1, and a transfer robot 718 with a hand for holding the substrate.

The mounting member 710-1 is a member for attaching the elevating rail 716 and the transfer robot 718 to the side surface of the plating chamber 401. The mounting member 710-1 includes a plurality of (in this embodiment, three) traveling rails 714 (714-1 to 714-3) that are fixed to the side surface of the plating chamber 401 and extend in the travel direction (the X direction). While this embodiment illustrates an example in which the three traveling rails 714 are provided to increase the stiffness of the mounting member 710-1, the traveling rails 714 are not limited thereto, and the two traveling rails (the traveling rails 714-1, 714-2 or the traveling rails 714-1, 714-3) may be provided.

The elevating rail 716 extends in an elevating direction across side surfaces of the plurality of traveling rails 714 and is configured to be movable along the side surfaces of the plurality of traveling rails 714. The elevating rail 716 is configured to move along the traveling rails 714 by a drive member (for example, a motor) that is not illustrated.

The transfer robot 718 is a member that is movable vertically along the elevating rail 716. Specifically, the transfer robot 718 is configured to be movable vertically along the elevating rail 716 by a drive member (for example, a motor) that is not illustrated. The transfer device 700 can transfer the substrate in the X and Z directions by moving the elevating rail 716 in the travel direction and moving the transfer robot 718 in the elevating direction. Thus, the transfer device 700 can transfer the substrate in front of a substrate loading/unloading port of the processing module as a transfer destination of the substrate.

Further, the transfer robot 718 is configured to be able to turn the hand about the elevating rail 716 in a horizontal plane. Thus, after the substrate is transferred in front of the substrate loading/unloading port, the transfer robot 718 can transfer the substrate via the mounting member 710-1 into the processing module by turning the hand. Note that the transfer robot 718 is configured to be able to reverse the top and bottom of the horizontally held substrate. As a result, the transfer robot 718 can reverse, for example, the substrate on which the plating process has been performed with the surface to be plated facing downward and transfer the substrate with the surface to be plated facing upward to the spin rinse dryer 600.

### Exhaust Configuration of Plating Apparatus

As illustrated in FIGS. 2B and 2C, the plating apparatus 1000 includes a fan filter unit 408 disposed above the substrate transfer chamber 701. The fan filter unit 408 is an example of a fan module configured to supply a gas to the substrate transfer chamber 701.

The plating chamber 401 includes a supply port 404 for supplying the gas supplied to the substrate transfer chamber 701 by the fan filter unit 408 to the plating chamber 401, and a discharge port 405 for discharging the gas supplied to the plating chamber 401 to the outside. The supply port 404 may have a hole or a slit formed on a side wall of the plating chamber 401, or may be shared with the substrate loading/unloading port. In other words, the substrate loading/unloading port is formed on the side wall of the plating chamber 401 to transfer the substrates between the plating module 400 and the transfer device 700. The supply port 404 may include a plurality of holes or slits formed in a plate member arranged at the substrate loading/unloading port. This allows the gas to be supplied via the slits when no substrate is being transferred between the plating module 400 and the transfer device 700, and allows the plate member to be moved to supply the gas from the substrate loading/unloading port when the substrate is being transferred. The discharge port 405 may include a hole or a slit formed on a top wall of each plating chamber 401. The discharge port 405 is connected to an exhaust system of a facility at the facility where the plating apparatus 1000 is installed.

The plating apparatus 1000 includes an exhaust chamber 702 disposed below the substrate transfer chamber 701, and a partition member 720 disposed between the substrate transfer chamber 701 and the exhaust chamber 702. In this embodiment, the partition member 720 is a plate-shaped member disposed between the substrate transfer chamber 701 and the exhaust chamber 702. However, the partition member 720 can be any member that can block the passage of the gas between the substrate transfer chamber 701 and the exhaust chamber 702.

The plating apparatus 1000 includes a process chamber 501 disposed below the plating chamber 401. The process chamber 501 houses a reservoir tank 510 that stores the plating solution to be used in the plating module 400. The process chamber 501 includes a first bypass opening 503 communicating with the substrate transfer chamber 701, and a second bypass opening 505 communicating with the exhaust chamber 702. The first bypass opening 503 is formed such that a bottom of the side wall of the substrate transfer chamber 701 and the process chamber 501 communicate.

The plating apparatus 1000 includes a bypass flow channel 730 through which the substrate transfer chamber 701 and the exhaust chamber 702 communicate by bypassing the partition member 720. The bypass flow channel 730 is formed by the first bypass opening 503, the second bypass opening 505, and a space in the process chamber 501. The exhaust chamber 702 has an exhaust outlet 703 for discharging the gas supplied to the exhaust chamber 702 via the bypass flow channel 730 to the outside. The exhaust outlet 703 can be configured with a plurality of slits formed on a bottom wall of the exhaust chamber 702 in this embodiment. The exhaust outlet 703 is connected to the exhaust system of the facility at the facility where the plating apparatus 1000 is installed.

With the embodiment, it is possible to achieve the substrate processing apparatus that can efficiently clean the inside of the apparatus. Namely, supplying the gas from the fan filter unit 408 to the substrate transfer chamber 701 allows forming a downflow of clean air in the substrate transfer chamber 701, thus causing particles and the like in the substrate transfer chamber 701 to flow in a direction of a bottom surface of the substrate transfer chamber 701.

Here, the plating apparatus 1000 of this embodiment includes the partition member 720 on the bottom surface of the substrate transfer chamber 701, which creates a flow resistance to the downflow. Therefore, the clean air supplied to the substrate transfer chamber 701 can easily flow to the plating chamber 401 via the supply port 404. The clean air supplied to the plating chamber 401 can discharge particles, mist of the plating solution, and the like present in the plating chamber 401 from the discharge port 405. In other words, the substrate transfer chamber 701 is at a positive pressure with respect to the plating chamber 401, and thus, the particles, the mist of the plating solution, and the like in the plating chamber 401 can be prevented from flowing out to the substrate transfer chamber 701 and from contaminating the substrate after the process.

The plating apparatus 1000 includes the bypass flow channel 730 through which the substrate transfer chamber 701 and the exhaust chamber 702 communicate. Thus, the particles that have flowed in the direction of the bottom surface of the substrate transfer chamber 701 can be sent to the exhaust chamber 702 via the bypass flow channel 730 and discharged from the exhaust outlet 703. In particular, since the first bypass opening 503 is formed such that the bottom of the side wall of the substrate transfer chamber 701 and the process chamber 501 communicate, the particles that have flowed downward by the downflow and then changed direction by the partition member 720 can be smoothly discharged from the first bypass opening 503 (the bypass flow channel 730).

The plating apparatus 1000 of this embodiment includes the bypass flow channel 730 formed by using the space in the process chamber 501. Therefore, not only when particles are generated in the process chamber 501, but also when mist of the plating solution is generated in the process chamber 501 from the system of the reservoir tank 510, these can be sent to the exhaust chamber 702 via the bypass flow channel 730 and discharged from the exhaust outlet 703. As described above, the plating apparatus 1000 of this embodiment can efficiently and appropriately clean the inside of the plating apparatus 1000 without increasing the number of fan filter unit 408 or increasing their sizes.

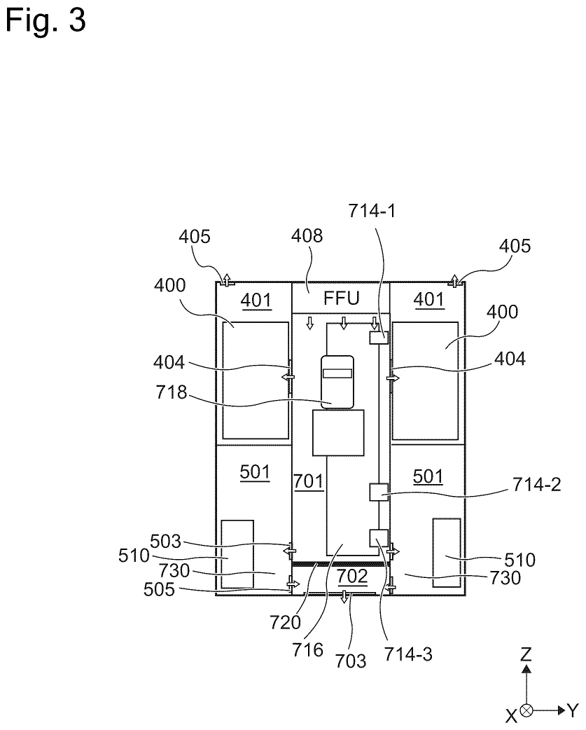

The above-described embodiment illustrates an example in which the plating modules 400 are arranged in two levels vertically, but the plating modules 400 are not limited thereto. FIG. 3 is a cross-sectional view of a plating apparatus of a modification. As illustrated in FIG. 3, the plating apparatus 1000 may have the plating modules 400 arranged in a single level vertically.

In this case, the size of the process chamber 501 in the vertical direction is relatively large, but the first bypass opening 503 is preferably formed such that the bottom of the side wall of the substrate transfer chamber 701 and the process chamber 501 communicate. This is for smoothly discharging the particles that flow in a direction changed by the partition member 720 after having flowed downward by the downflow of the substrate transfer chamber 701, from the first bypass opening 503 (the bypass flow channel 730).

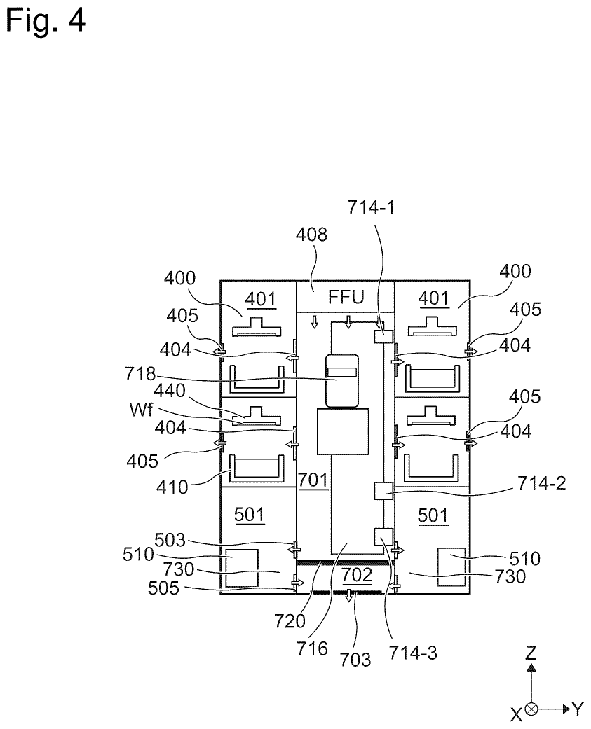

The above-described embodiment illustrates an example in which the discharge port 405 is disposed on the top wall of the plating chamber 401, but the discharge port 405 is not limited thereto. FIG. 4 is a cross-sectional view of a plating apparatus of a modification. As illustrated in FIG. 4, the plating module 400 includes a plating tank 410 that contains the plating solution and a substrate holder 440 that holds a substrate Wf with the surface to be plated facing downward. In this case, the discharge port 405 is preferably disposed on the side wall of the plating chamber 401, higher than the plating tank 410 and lower than a height position of the substrate holder 440 when the substrate Wf is transferred between the discharge port 405 and the transfer device 700 (the transfer robot 718).

With the modification, mist of the plating solution generated from the plating tank 410 can be quickly discharged from the discharge port 405. As a result, it is possible to suppress the formation of rust and the like on the substrate holder 440 and other mechanical parts of the plating module 400 due to the mist of the plating solution.

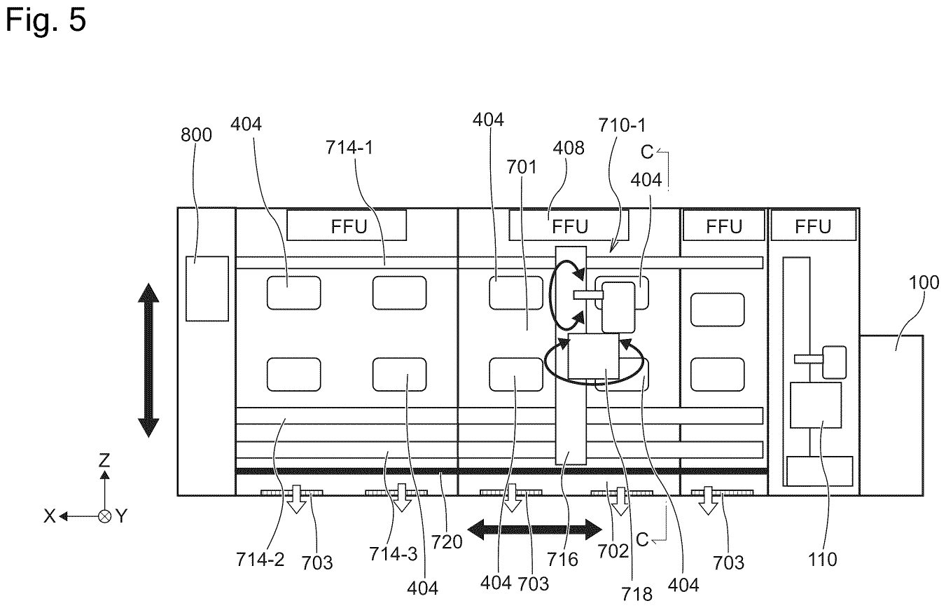

The above-described embodiment illustrates an example in which the common exhaust outlet 703 is formed on the bottom wall of the exhaust chamber 702 for 16 plating modules 400, but the exhaust outlet 703 is not limited thereto. FIG. 5 is a cross-sectional view of a plating apparatus of a modification. As illustrated in FIG. 5, a plurality of the exhaust outlets 703 may be disposed individually for the four plating modules 400. Since providing the exhaust outlets 703 individually can separate the exhaust systems, the particles and the like can be prevented from mixing with one another in each exhaust system, and each system can be independently controlled for exhaust.

While several embodiments of the present invention have been described above, the above-described embodiments of the invention are intended to facilitate understanding of the present invention and are not intended to limit the present invention. The present invention can be changed or improved without departing from the gist thereof, and it is a matter of course that the equivalents of the present invention are included in the present invention. To the extent that at least part of the above-described problems can be solved, or to the extent that at least part of the effect is achieved, any combination or omission of each component described in the claims and the specification is possible.

This application discloses, as one embodiment, a substrate processing apparatus including a substrate transfer chamber, a fan module, a plating chamber, an exhaust chamber, a partition member, and a bypass flow channel. The substrate transfer chamber houses a transfer device for transferring a substrate. The fan module is disposed above the substrate transfer chamber and configured to supply a gas to the substrate transfer chamber. The plating chamber is disposed on a side of the substrate transfer chamber and houses a plating module for performing a plating process on the substrate. The exhaust chamber is disposed below the substrate transfer chamber. The partition member is disposed between the substrate transfer chamber and the exhaust chamber. The substrate transfer chamber and the exhaust chamber communicate through the bypass flow channel by bypassing the partition member. The plating chamber has a supply port for supplying the gas supplied to the substrate transfer chamber by the fan module to the plating chamber, and a discharge port for discharging the gas supplied to the plating chamber to outside. The exhaust chamber has an exhaust outlet for discharging the gas supplied to the exhaust chamber via the bypass flow channel to outside.

Furthermore, this application discloses, as one embodiment, the substrate processing apparatus in which the discharge port is disposed on a top wall of the plating chamber.

Furthermore, this application discloses, as one embodiment, the substrate processing apparatus in which the plating module includes a plating tank containing a plating solution, and a substrate holder holding the substrate with a surface to be plated facing downward, and the discharge port is disposed higher than the plating tank and lower than a height position of the substrate holder when the substrate is transferred between the discharge port and the transfer device.

Furthermore, this application discloses, as one embodiment, the substrate processing apparatus further including a process chamber disposed below the plating chamber and housing a reservoir tank storing a plating solution to be used in the plating module. The process chamber has a first bypass opening communicating with the substrate transfer chamber, and a second bypass opening communicating with the exhaust chamber, and the bypass flow channel is formed by the first bypass opening, the second bypass opening, and a space in the process chamber.

Furthermore, this application discloses, as one embodiment, the substrate processing apparatus in which the plating chambers are disposed on respective both sides of the substrate transfer chamber in a travel direction of the transfer device.

### Reference Signs List

400 . . . plating module
401 . . . plating chamber
404 . . . supply port
405 . . . discharge port
408 . . . fan filter unit
410 . . . plating tank
440 . . . substrate holder
501 . . . process chamber
503 . . . first bypass opening
505 . . . second bypass opening
510 . . . reservoir tank
700 . . . transfer device
701 . . . substrate transfer chamber
702 . . . exhaust chamber
703 . . . exhaust outlet
720 . . . partition member
730 . . . bypass flow channel
1000 . . . plating apparatus
Wf . . . substrate

1. A substrate processing apparatus comprising:
a substrate transfer chamber housing a transfer device for transferring a substrate;
a fan module disposed above the substrate transfer chamber and configured to supply a gas to the substrate transfer chamber;
a plating chamber disposed on a side of the substrate transfer chamber and housing a plating module for performing a plating process on the substrate;
an exhaust chamber disposed below the substrate transfer chamber;
a partition member disposed between the substrate transfer chamber and the exhaust chamber; and
a bypass flow channel through which the substrate transfer chamber and the exhaust chamber communicate by bypassing the partition member, wherein
the plating chamber has a supply port for supplying the gas supplied to the substrate transfer chamber by the fan module to the plating chamber, and a discharge port for discharging the gas supplied to the plating chamber to outside, and
the exhaust chamber has an exhaust outlet for discharging the gas supplied to the exhaust chamber via the bypass flow channel to outside.

2. The substrate processing apparatus according to claim 1, wherein
the discharge port is disposed on a top wall of the plating chamber.

3. The substrate processing apparatus according to claim 1, wherein
the plating module includes a plating tank containing a plating solution, and a substrate holder holding the substrate with a surface to be plated facing downward, and
the discharge port is disposed higher than the plating tank and lower than a height position of the substrate holder when the substrate is transferred between the discharge port and the transfer device.

4. The substrate processing apparatus according to claim 1, further comprising
a process chamber disposed below the plating chamber and housing a reservoir tank storing a plating solution to be used in the plating module, wherein
the process chamber has a first bypass opening communicating with the substrate transfer chamber, and a second bypass opening communicating with the exhaust chamber, and
the bypass flow channel is formed by the first bypass opening, the second bypass opening, and a space in the process chamber.

5. The substrate processing apparatus according to claim 1, wherein
the plating chambers are disposed on respective both sides of the substrate transfer chamber in a travel direction of the transfer device.
